(19) United States
(12) Patent Application Publication
(10) Pub. No.: US 2024/0294337 A1
(43) Pub. Date: Sep. 5, 2024

(54) Article Transport Facility

(71) Applicant: Daifuku Co., Ltd., Osaka-shi (JP)

(72) Inventors: Takahiro Sebe, Komaki-shi (JP); Shinichiro Higashi, Komaki-shi (JP); Keita Yamada, Komaki-shi (JP)

(21) Appl. No.: 18/593,155

(22) Filed: Mar. 1, 2024

(30) Foreign Application Priority Data
Mar. 3, 2023 (JP) 2023-032812

(51) Int. Cl. B65G 1/137; B65G 1/04

(52) U.S. Cl. CPC B65G 1/1375; B65G 1/0407

(57) ABSTRACT

An article transport facility for transporting an article includes a first lifting and lowering transport device including a first transfer device, and a second lifting and lowering transport device including a second transfer device. The first transfer device lifts and lowers on a first path, the second transfer device lifts and lowers on a second path, and the first path and the second path are disposed not to overlap with each other as viewed vertically. The first path has a first target area including a lower end portion thereof, the second path has a second target area including an upper end portion thereof, and the first target area and the second target area are disposed in the same vertical range. The first transfer device and the second transfer device are both able to transfer the article to a shared storing section in which the article is storable.

### CROSS-REFERENCE TO RELATED APPLICATION

This application claims priority to Japanese Patent Application No. 2023-032812 filed Mar. 3, 2023, the disclosure of which is hereby incorporated by reference in its entirety.

### BACKGROUND OF THE INVENTION

### 1. Field of the Invention

The present invention relates to an article transport facility for transporting an article over a plurality of levels.

### 2. Description of Related Art

For example, Japanese Unexamined Patent Application Publication No. 2017-114618 (Patent Document 1) discloses a technology about an article transport facility for transporting an article over a plurality of levels. Hereinafter, reference signs described within parentheses in the Description of the Background Art are reference signs used in Patent Document 1.

The article transport facility of Patent Document 1 includes an interlevel transport device (K) configured to transport an article over a plurality of levels. The interlevel transport device (K) includes a first guide body (a first guiding mast M1) and a second guide body (a second guiding mast M2) disposed to extend vertically, a first transfer device (a first movable body T1) guided by the first guide body to lift and lower, and a second transfer device (a second movable body T2) guided by the second guide body to lift and lower. The first guide body is provided over a first level to a third level in the article transport facility. The second guide body is provided over the third level to a fifth level in the article transport facility. Each of the first movable body and the second movable body includes a transfer device that can transfer an article to a transfer target section. The first movable body transports an article to a transfer target section in each of the first level to the third level, and the second movable body transports an article to a transfer target section in each of the third level to the fifth level. Further, the third level has an area provided with a relay support base (N) on which an article is placeable, so that the first movable body and the second movable body can transfer an article to each other via the relay support base (N).

The article transport facility described in Patent Document 1 has an overlap area (herein, on the third level) where an area including an upper end portion of a path on which the first movable body moves overlaps with an area including a lower end portion of a path on which the second movable body moves. However, since the path of the first movable body and the path of the second movable body overlap with each other as viewed vertically, the first movable body and the second movable body cannot be placed at the same height without coming into contact with each other in such an overlap area. For this reason, there is such a problem that the first movable body and the second movable body cannot perform a transferring operation at the same time, and article transport efficiency of the whole facility is hard to be enhanced. In the meantime, in the article transport facility as described above, many articles are transported to each level. In view of this, it is also conceivable to enhance the article transport efficiency by securing a place for temporarily keeping articles to avoid a jam of articles to be transported or to switch transport orders, for example. However, Patent Document 1 does not mention anything about this point.

### SUMMARY OF THE INVENTION

In view of the foregoing, an article transport facility that can secure an article storage place and enhance article transport efficiency is desired as an article transport facility for transporting an article over a plurality of levels.

An article transport facility according to this disclosure is an article transport facility for transporting an article over a plurality of levels and includes: a first lifting and lowering transport device including a first guide body disposed to extend vertically, and a first transfer device configured to lift and lower on a first path along the first guide body and to transfer the article to and from a transfer target section; and a second lifting and lowering transport device including a second guide body disposed to extend vertically, and a second transfer device configured to lift and lower on a second path along the second guide body and to transfer the article to and from the transfer target section. The first path and the second path are disposed not to overlap with each other as viewed vertically. The first path has a first target area including a lower end portion of the first path, the second path has a second target area including an upper end portion of the second path, and the first target area and the second target area are disposed in the same vertical range. The first transfer device and the second transfer device are both able to transfer the article to a shared storing section in which the article is storable, the shared storing section being provided in an overlap area disposed in the same vertical range as the first target area and the second target area.

With this configuration, both the first transfer device and the second transfer device can store the article in the shared storing section and transfer the article to each other via the shared storing section. Accordingly, it is possible to easily secure a storage place for articles and to transfer articles over the whole area in a liftable range of the first transfer device and in a liftable range of the second transfer device. Further, in the above configuration, since the path of the first transfer device and the path of the second transfer device are disposed not to overlap with each other as viewed vertically, it is possible to dispose the first transfer device and the second transfer device at the same height. As a result, in a case where the first transfer device and the second transfer device separately lift and lower, they do not restrict each other, and hereby, it is possible to easily enhance article transport efficiency as the whole facility.

This configuration allows the article transport facility for transporting an article over a plurality of levels to secure a storage place for articles and to enhance article transport efficiency.

Further features and advantages of the article transport facility are made clear from the following description on exemplary and nonlimiting embodiments to be described with reference to the drawings.

### BRIEF DESCRIPTION OF THE DRAWINGS

FIG. 1 is a general front view of an article transport facility;

FIG. 2 is a plan view schematically illustrating an overlap area;

FIG. 3 is a plan view schematically illustrating the arrangement of a first cylindrical body, a second cylindrical body, and an intermediate cylindrical body;

FIG. 4 is a side view schematically illustrating transfer of an article by a first transfer device;

FIG. 5 is a side view schematically illustrating a combination transport device;

FIG. 6 is a control block diagram;

FIG. 7 is a control flow diagram;

FIG. 8 is a plan view schematically illustrating an overlap area in an alternative embodiment;

FIG. 9 is a plan view schematically illustrating an overlap area in an alternative embodiment; and

FIG. 10 is a plan view schematically illustrating the arrangement of a first cylindrical body, a second cylindrical body, and an intermediate cylindrical body in an alternative embodiment.

### DESCRIPTION OF THE INVENTION

An article transport facility is a facility for transporting or storing raw materials, intermediate products, finished products, and the like, for example. The following describes embodiments of the article transport facility with reference to the drawings.

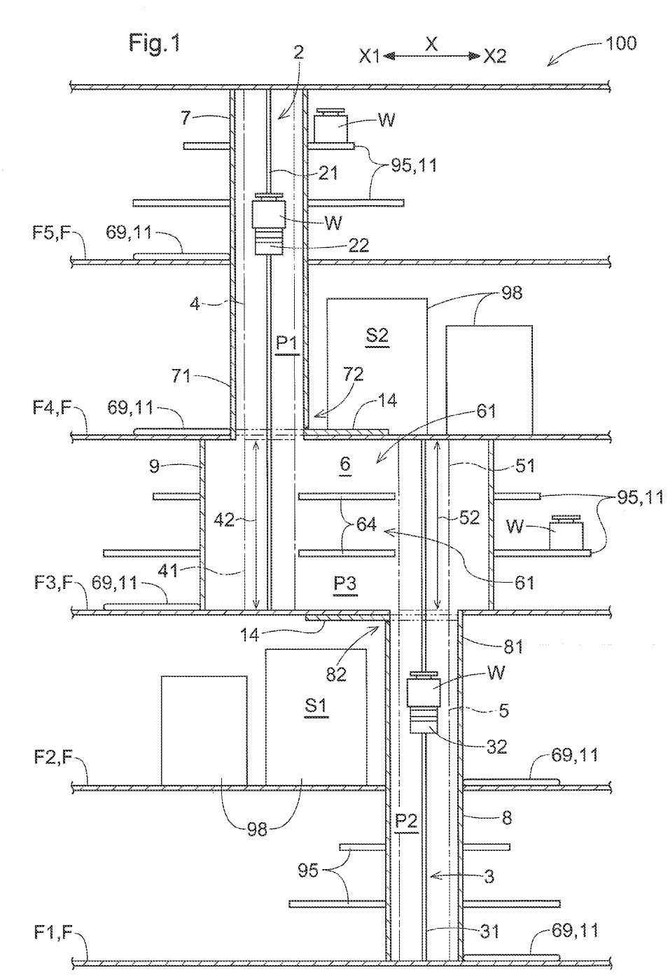

As illustrated in FIG. 1, an article transport facility 100 is configured to transport an article W over a plurality of levels. In the present embodiment, the article transport facility 100 is provided in a building including a plurality of floors F. The article transport facility 100 can transport a plurality of articles W to each of the plurality of levels. Further, the article transport facility 100 can store a plurality of articles W. An example of the article W is a storage container (a FOUP (Front Opening Unified Pod), a reticle pod, or the like) containing a semiconductor substrate, a reticle substrate, or the like, for example. It is assumed that such an article transport facility 100 is provided in a clean room for performing processing or the like on raw materials under a clean environment, for example.

In the present embodiment, the article transport facility 100 includes a first lifting and lowering transport device 2 and a second lifting and lowering transport device 3. The article transport facility 100 also includes a first cylindrical body 7, a second cylindrical body 8, and an intermediate cylindrical body 9. Each of the first lifting and lowering transport device 2 and the second lifting and lowering transport device 3 can transport the article W over a plurality of levels and can transfer the article W to a plurality of transfer target sections 11 (described later). The following describes the configuration of each of the first lifting and lowering transport device 2 and the second lifting and lowering transport device 3. Note that an arrangement direction X is defined as a direction which is along a horizontal plane and in which the first lifting and lowering transport device 2 and the second lifting and lowering transport device 3 are arranged, a first side X1 in the arrangement direction is defined as a side where the first lifting and lowering transport device 2 is disposed relative to the second lifting and lowering transport device 3, and a second side X2 in the arrangement direction is defined as a side opposite to the first side X1 (a side where the second lifting and lowering transport device 3 is disposed relative to the first lifting and lowering transport device 2).

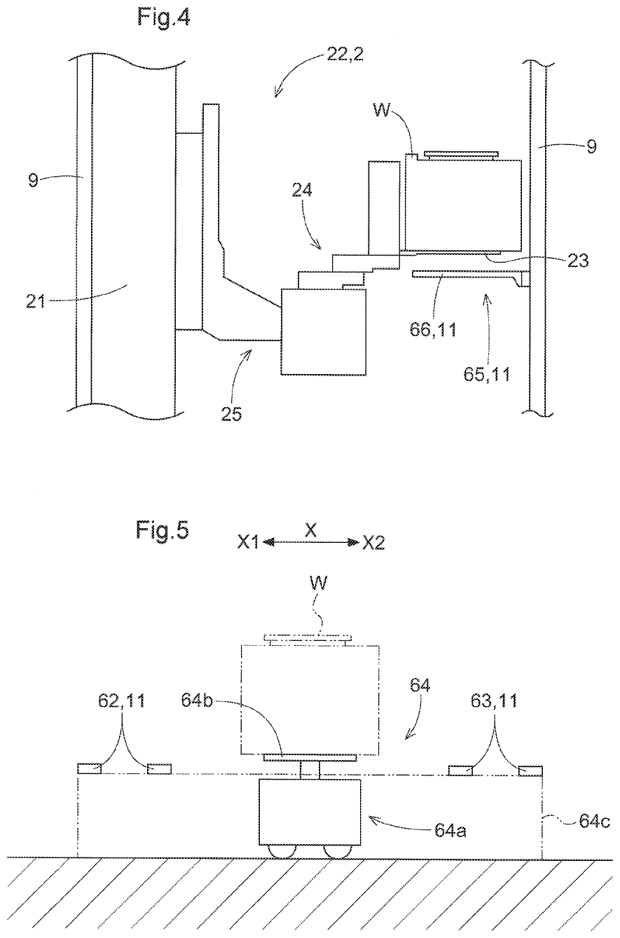

As illustrated in FIGS. 1, 2, and 4, the first lifting and lowering transport device 2 includes a first guide body 21 disposed to extend vertically, and a first transfer device 22 configured to lift and lower along the first guide body 21 to transfer the article W to and from the transfer target section 11. In the present embodiment, the first guide body 21 is disposed over a plurality of levels. On this account, the first transfer device 22 is guided by the first guide body 21 to move over the plurality of levels. As illustrated in FIGS. 1, 4, the first transfer device 22 includes a lifting and lowering table 25 attached to the first guide body 21 such that the lifting and lowering table 25 can lift and lower, a transfer mechanism 24 supported by the lifting and lowering table 25, and a support 23 configured to support the article W. In response to the lifting and lowering table 25 lifting and lowering along the first guide body 21, the transfer mechanism 24 and the support 23 lift and lower. In the example of FIG. 4, the transfer mechanism 24 includes a turning section (not illustrated) configured to turn the support 23 around an axial center extending vertically, and an advancing and retracting section (not illustrated) configured to advance and retract the support 23 horizontally. Herein, the transfer mechanism 24 is constituted by use of a horizontal articulated arm (so-called SCARA (Selective Compliance Assembly Robot Arm)).

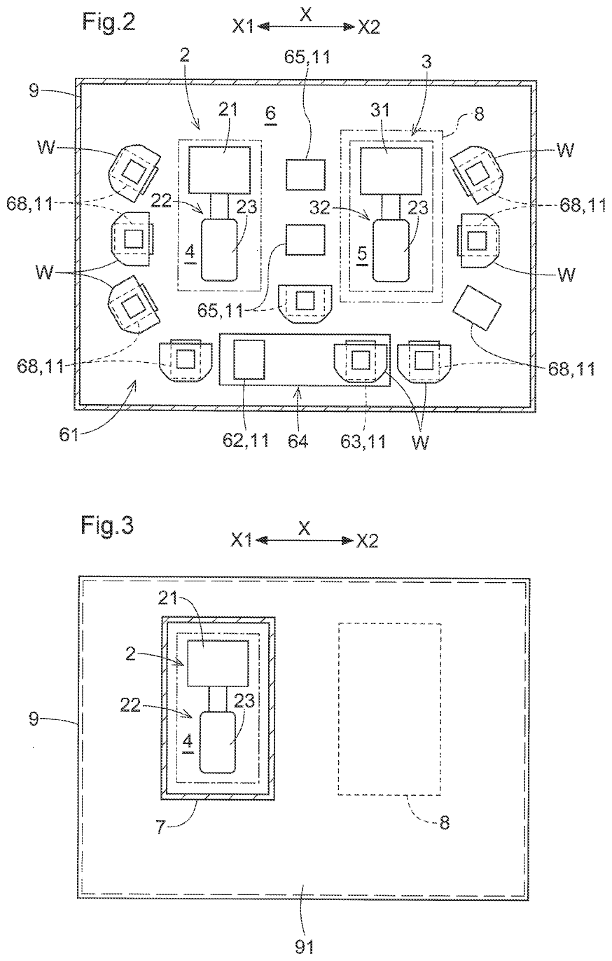

As illustrated in FIGS. 1, 2, the second lifting and lowering transport device 3 includes a second guide body 31 disposed to extend vertically, and a second transfer device 32 configured to lift and lower along the second guide body 31 to transfer the article W to and from the transfer target section 11. In the present embodiment, the second guide body 31 is disposed over a plurality of levels. On this account, the second transfer device 32 is guided by the second guide body 31 to move over the plurality of levels. Since the second transfer device 32 has the same structure as the first transfer device 22, the second transfer device 32 is not illustrated in detail. However, the second transfer device 32 includes a lifting and lowering table 25 attached to the second guide body 31 such that the lifting and lowering table 25 can lift and lower, a transfer mechanism 24 supported by the lifting and lowering table 25, and a support 23 configured to support the article W. In response to the lifting and lowering table 25 lifting and lowering along the second guide body 31, the transfer mechanism 24 and the support 23 lift and lower. Note that, as the transfer mechanism 24 of each of the first transfer device 22 and the second transfer device 32, a fork-type mechanism that moves the support 23 horizontally or a chuck-type mechanism that grips the article W by a gripper is also employable. The following describes a case where the article W is transferred to the transfer target section 11 by the first transfer device 22 or the second transfer device 32. In the example of FIG. 4, the transfer target section 11 is a plate-shaped shelf body. The shelf body is partially cut such that the support 23 is movable vertically. When the support 23 on which the article W is placed is disposed above the shelf body in response to movement of the horizontal articulated arm, the lifting and lowering table 25 lowers. In response to the lowering of the lifting and lowering table 25, the support 23 lowers and passes through a notch of the shelf body. Since the article W cannot pass through the notch of the shelf body, the article W remains on the shelf body, and thus, the article W is placed on the shelf body. Note that, in a case where the first transfer device 22 or the second transfer device 32 receives the article W on the shelf body, an operation reverse to the above is performed.

In the present embodiment, the first guide body 21 and the second guide body 31 are disposed apart from each other in the arrangement direction X and are also disposed at respective positions vertically deviating from each other. More specifically, the first guide body 21 and the second guide body 31 are disposed apart from each other such that respective paths (a first path 4 and a second path 5) on which the first transfer device 22 and the second transfer device 32 lift and lower do not interfere with each other. Further, a part including a lower end portion of the first guide body 21 and a part including an upper end portion of the second guide body 31 are disposed in the same vertical range. In the present example, an upper end portion of the first guide body 21 is disposed above the upper end portion of the second guide body 31, and the lower end portion of the first guide body 21 is disposed above a lower end portion of the second guide body 31 but below the upper end portion of the second guide body 31. In the example of FIG. 1, each of the first guide body 21 and the second guide body 31 is a mast allowing the lifting and lowering table 25 to move vertically. The first guide body 21 is disposed over the whole area from a floor F3 on a third level to a ceiling on a fifth level among five levels. The second guide body 31 is disposed over the whole area from a floor F1 on a first level to a ceiling on the third level. That is, the first guide body 21 and the second guide body 31 are disposed in the same vertical range on the third level (herein, from the floor F3 on the third level to the ceiling on the third level). Since the guide bodies are disposed as such, the first transfer device 22 lifts and lowers in a range from the third level to the fifth level, and the second transfer device 32 lifts and lowers in a range from the first level to the third level.

As illustrated in FIGS. 1, 2, in the present embodiment, the first path 4 as the path on which the first transfer device 22 lifts and lowers and the second path 5 as the path on which the second transfer device 32 lifts and lowers are disposed not to overlap with each other as viewed vertically. The first path 4 is formed along the first guide body 21. The second path 5 is formed along the second guide body 31. As described above, the first guide body 21 and the second guide body 31 are apart from each other in the arrangement direction X such that respective paths of the first transfer device 22 and the second transfer device 32 do not interfere with each other. Accordingly, the first path 4 and the second path 5 do not overlap with each other as viewed vertically. In the present embodiment, the first path 4 is a path on the first transfer device 22 moves from its lifting and lowering upper limit to its lifting and lowering lower limit, and the second path 5 is a path on the second transfer device 32 moves from its lifting and lowering upper limit to its lifting and lowering lower limit. In the example illustrated herein, the first path 4 is formed over a plurality of levels from the third level to the fifth level. The second path 5 is formed over a plurality of levels from the first level to the third level.

Further, as illustrated in FIGS. 1, 2, the first path 4 has a first target area 42 including a lower end portion 41 of the first path 4 and the second path 5 has a second target area 52 including an upper end portion 51 of the second path 5 such that the first target area 42 and the second target area 52 are disposed in the same vertical range. An overlap area 6 (described later) is disposed in the same vertical range as the first target area 42 and the second target area 52. In the present embodiment, the first target area 42 is an area including the lower end portion 41 of the first path 4 and disposed below a vertically intermediate portion of the first path 4, and the second target area 52 is an area including the upper end portion 51 of the second path 5 and disposed above a vertically intermediate portion of the second path 5. That is, an upper end portion of the first path 4 is disposed above the upper end portion 51 of the second path 5, and the lower end portion 41 of the first path 4 is disposed above a lower end portion of the second path 5 but below the upper end portion 51 of the second path 5. Herein, the overlap area 6 includes an area where the first path 4 and the second path 5 overlap with each other as viewed in the arrangement direction X. In the example of FIG. 1, the first path 4 is formed over the whole vertical area from the third level to the fifth level. The second path 5 is formed over the whole vertical area from the first level to the third level. The first path 4 and the second path 5 are disposed in the same range in the whole vertical area of one level (herein, the third level) from among the plurality of levels. That is, in the present example, the first target area 42 is a part of the first path 4 which part is disposed on the one level, and the second target area 52 is a part of the second path 5 which part is disposed on the one level. The first path 4 and the second path 5 overlap with each other as viewed in the arrangement direction X on the one level from among the plurality of levels. Further, in the example of FIG. 2, the first path 4 and the second path 5 are disposed along the arrangement direction X and apart from each other. Herein, the overlap area 6 is the whole area of an internal space P3 of the intermediate cylindrical body 9 disposed in one level from among the plurality of levels. Note that part of the overlap area 6 and part of the internal space P3 of the intermediate cylindrical body 9 may be disposed to deviate from each other vertically or horizontally. A specific configuration of the intermediate cylindrical body 9 will be described later.

As illustrated in FIGS. 1, 3, the first cylindrical body 7 is disposed to extend vertically and contains the first lifting and lowering transport device 2. The first cylindrical body 7 is disposed over a plurality of levels along the first guide body 21. Further, the first cylindrical body 7 is formed with a size corresponding to each of the first lifting and lowering transport device 2 and the first path 4. More specifically, the first cylindrical body 7 is formed with a size in which the first lifting and lowering transport device 2 (the first guide body 21, the first transfer device 22) is stored and which covers the first path 4. In the present embodiment, as illustrated in FIG. 1, the first cylindrical body 7 is disposed above the intermediate cylindrical body 9, and its lower end portion 71 is connected to the intermediate cylindrical body 9. On this account, the first cylindrical body 7 contains a portion of the first guide body 21 which portion is above a portion thereof stored in the intermediate cylindrical body 9 (a portion present in the overlap area 6). Similarly, the first cylindrical body 7 is formed to cover a portion of the first path 4 which portion is above a portion thereof formed in the internal space P3 of the intermediate cylindrical body 9 (a portion formed in the overlap area 6 and corresponding to the first target area 42 described above). In the present example, the first cylindrical body 7 is made of a hollow (tubular) member extending vertically. Further, the first cylindrical body 7 is provided to rise from an upper surface 91 of the intermediate cylindrical body 9. An internal space P1 of the first cylindrical body 7 communicates with the overlap area 6 (herein, the internal space P3 of the intermediate cylindrical body 9).

As illustrated in FIGS. 1, 3, the second cylindrical body 8 is disposed to extend vertically and contains the second lifting and lowering transport device 3. The second cylindrical body 8 is disposed over a plurality of levels along the second guide body 31. Further, the second cylindrical body 8 is formed with a size corresponding to each of the second lifting and lowering transport device 3 and the second path 5. More specifically, the second cylindrical body 8 is formed with a size in which the second lifting and lowering transport device 3 (the second guide body 31, the second transfer device 32) is stored and which cover the second path 5. In the present embodiment, as illustrated in FIG. 1, the second cylindrical body 8 is disposed below the intermediate cylindrical body 9, and its upper end portion 81 is connected to the intermediate cylindrical body 9. On this account, the second cylindrical body 8 contains a portion of the second guide body 31 which portion is below a portion thereof stored in the intermediate cylindrical body 9 (a portion present in the overlap area 6). Similarly, the second cylindrical body 8 is formed to cover a portion of the second path 5 which portion is below a portion thereof formed in the internal space P3 of the intermediate cylindrical body 9 (a portion formed in the overlap area 6 and corresponding to the second target area 52 described above). In the present example, the second cylindrical body 8 is made of a hollow (tubular) member extending vertically. The second cylindrical body 8 is provided to extend downward from a lower surface of the intermediate cylindrical body 9. An internal space P2 of the second cylindrical body 8 communicates with the overlap area 6 (herein, the internal space P3 of the intermediate cylindrical body 9). By the way, the term “cover” in the present embodiment indicates that a path (the first path 4, the second path 5) is present in a given space (e.g., the internal space P1 of the first cylindrical body 7 and the internal space P2 of the second cylindrical body 8).

Note that, in the example of FIG. 3, the first cylindrical body 7 and the second cylindrical body 8 are each formed in a rectangular shape in a plan view. However, they are not limited to this and may have a circular shape, a polygonal shape, or the like in a plan view, for example. Further, the first cylindrical body 7 and the second cylindrical body 8 may have different shapes in a plan view.

As illustrated from FIGS. 1 to 3, the intermediate cylindrical body 9 contains the first guide body 21 and the second guide body 31 in the overlap area 6. The intermediate cylindrical body 9 is disposed vertically between the first cylindrical body 7 and the second cylindrical body 8 to connect the first cylindrical body 7 to the second cylindrical body 8. The intermediate cylindrical body 9 is formed with a size corresponding to the overlap area 6. That is, the intermediate cylindrical body 9 is formed to define the overlap area 6. Further, the intermediate cylindrical body 9 contains respective portions of the first guide body 21 and the second guide body 31, the respective portions being in the same vertical range as the overlap area 6. Hereby, the intermediate cylindrical body 9 can include, in the internal space P3, respective areas of the first path 4 and the second path 5, the respective areas being in the same vertical range as the overlap area 6. In the example of FIG. 3, the intermediate cylindrical body 9 is disposed to overlap with the first cylindrical body 7 and the second cylindrical body 8 in a plan view. Further, the first cylindrical body 7 and the second cylindrical body 8 (a broken-line portion in FIG. 3) are disposed along the arrangement direction X to be apart from each other, and they do not overlap with each other in a plan view. As such, in the present embodiment, the first cylindrical body 7 and the second cylindrical body 8 are disposed not to overlap with each other as viewed vertically.

In the example of FIG. 1, the intermediate cylindrical body 9 is provided at one level (herein, the third level) from among the plurality of levels. More specifically, the intermediate cylindrical body 9 is provided on the floor F3 on the third level, from the floor F3 on the third level to the ceiling on the third level. Note that the overlap area 6 may be formed over a plurality of levels, and in response to this, the intermediate cylindrical body 9 may be also provided over the plurality of levels. The intermediate cylindrical body 9 is made of a hollow (tubular) member extending vertically. In the example of FIG. 3, the intermediate cylindrical body 9 is formed in a rectangular shape in a plan view. However, the intermediate cylindrical body 9 is not limited to this and may have a circular shape, a polygonal shape, or the like in a plan view, for example.

In the present embodiment, as illustrated in FIG. 1, a first arrangement space S1 where other members or devices are arrangeable is provided on a side vertically opposite to the first cylindrical body 7 across the intermediate cylindrical body 9. In the present example, as illustrated in FIG. 1, the first arrangement space S1 is set in a space below the intermediate cylindrical body 9, the space overlapping with the intermediate cylindrical body 9 but not overlapping with the second cylindrical body 8 in a plan view. In other words, the first arrangement space S1 is set to be adjacent to the first side X1, in the arrangement direction, of the second cylindrical body 8. In the example illustrated herein, the first arrangement space S1 is defined as a space below the intermediate cylindrical body 9 and on a side (the first side X1 in the arrangement direction relative to the second cylindrical body 8) where the first cylindrical body 7 is disposed relative to the second cylindrical body 8 in a range overlapping with the intermediate cylindrical body 9 in a plan view. The first arrangement space S1 is also set on a level (herein, the second level) below the level on which the intermediate cylindrical body 9 is disposed.

Further, in the present embodiment, as illustrated in FIG. 1, a second arrangement space S2 where other members or devices are arrangeable is provided on a side vertically opposite to the second cylindrical body 8 across the intermediate cylindrical body 9. In the present example, as illustrated in FIG. 1, the second arrangement space S2 is set in a space above the intermediate cylindrical body 9, the space overlapping with the intermediate cylindrical body 9 but not overlapping with the first cylindrical body 7 in a plan view. In other words, the second arrangement space S2 is set to be adjacent to the second side X2, in the arrangement direction, of the first cylindrical body 7. In the example illustrated herein, the second arrangement space S2 is set above the intermediate cylindrical body 9 and horizontally on a side where the second cylindrical body 8 is disposed relative to the first cylindrical body 7 in a range overlapping with the intermediate cylindrical body 9 in a plan view. Further, the second arrangement space S2 is set on a level (herein, the fourth level) above the level on which the intermediate cylindrical body 9 is disposed. Thus, the second arrangement space S2 is set above the first arrangement space S1 across the intermediate cylindrical body 9.

In the example of FIG. 1, in each of the first arrangement space S1 and the second arrangement space S2, a device for performing processing on the article W as a transport target (e.g., in a case where the article W is a container, a processing device for a semiconductor substrate, a reticle substrate, or the like stored in the container), a storage shelf for the article W, or the like can be disposed. Further, in each of the first arrangement space S1 and the second arrangement space S2, a guide rail for an overhead transport vehicle, or the like, may be disposed. As such, the first arrangement space S1 and the second arrangement space S2 are spaces where various devices 98, a guide rail, and the like can be disposed as needed. Note that, herein, each of the first arrangement space S1 and the second arrangement space S2 is set on one level but may be also set over a plurality of levels.

As illustrated in FIG. 1, in the present embodiment, at least one of a coupler 72 between the first cylindrical body 7 and the intermediate cylindrical body 9 and a coupler 82 between the second cylindrical body 8 and the intermediate cylindrical body 9 includes a fire door 14. In the present example, the coupler 72 between the first cylindrical body 7 and the intermediate cylindrical body 9 and the coupler 82 between the second cylindrical body 8 and the intermediate cylindrical body 9 both include respective fire doors 14. In the example illustrated herein, the fire door 14 is a sliding door. The fire door 14 provided in the coupler 72 between the first cylindrical body 7 and the intermediate cylindrical body 9 is configured to expose and block an area which overlaps with the internal space P1 of the first cylindrical body 7 as viewed vertically and which does not overlap with the internal space P2 of the second cylindrical body 8 as viewed vertically. In the present example, the fire door 14 provided in the coupler 72 between the first cylindrical body 7 and the intermediate cylindrical body 9 is disposed to cover a whole boundary area between the internal space P1 of the first cylindrical body 7 and the internal space P3 of the intermediate cylindrical body 9 while the fire door 14 is closed (an alternate long and two short dashes line in FIG. 1). Further, the fire door 14 provided in the coupler 82 between the second cylindrical body 8 and the intermediate cylindrical body 9 is configured to expose and block an area which overlaps with the internal space P2 of the second cylindrical body 8 as viewed vertically and which does not overlap with the internal space P1 of the first cylindrical body 7 as viewed vertically. In the present example, the fire door 14 provided in the coupler 82 between the second cylindrical body 8 and the intermediate cylindrical body 9 is disposed to cover a whole boundary area between the internal space P2 of the second cylindrical body 8 and the internal space P3 of the intermediate cylindrical body 9 while the fire door 14 is closed (an alternate long and two short dashes line in FIG. 1).

In the example of FIG. 1, the article transport facility 100 includes a conveyor section 69 as the transfer target section 11. The conveyor section 69 is provided on the floor F on each of the plurality of levels (a floor F1 on the first level to a floor F5 on the fifth level). The first lifting and lowering transport device 2 and the second lifting and lowering transport device 3 each can transfer the article W to the conveyor sections 69 provided on the floors F. Here, the conveyor section 69 is a well-known conveyor for transferring the article W between the level where the conveyor section 69 is provided and each of the first lifting and lowering transport device 2 and the second lifting and lowering transport device 3. Further, in the example of FIG. 1, each of the first cylindrical body 7, the second cylindrical body 8, and the intermediate cylindrical body 9 is connected to a transport conveyor 95. Each of the first lifting and lowering transport device 2 and the second lifting and lowering transport device 3 can also transfer the article W to such a transport conveyor 95. For example, the transport conveyor 95 can transfer the article W to and from an overhead transport vehicle (not illustrated). Note that, in FIG. 1, the article W as a transport target, a transfer device (the first transfer device 22, the second transfer device 32), and the like are illustrated larger than actual ones for easy understanding.

As illustrated in FIGS. 1, 2, a shared storing section 61 onto which both the first transfer device 22 and the second transfer device 32 can transfer the article W and in which the article W can be stored is provided in the overlap area 6. In the present embodiment, the shared storing section 61 is provided in the intermediate cylindrical body 9. In the shared storing section 61, the first transfer device 22 and the second transfer device 32 transfer the article W to each other, and the article W is temporarily stored. In the present example, a plurality of (herein, two) shared storing sections 61 is provided separately on the upper side and the lower side in the intermediate cylindrical body 9 (that is, in the internal space P3 of the intermediate cylindrical body 9). Further, the shared storing section 61 is disposed in the overlap area 6.

As illustrated in FIGS. 2 and 5, the shared storing section 61 includes a first transfer section 62 where the first transfer device 22 transfers the article W, a second transfer section 63 where the second transfer device 32 transfers the article W, and a combination transport device 64 configured to transport the article W between the first transfer section 62 and the second transfer section 63. In the present example, the first transfer section 62 and the second transfer section 63 are disposed at the same height. The combination transport device 64 is disposed to connect the first transfer section 62 to the second transfer section 63. Here, the combination transport device 64 is a conveyor device configured to transport the article W horizontally. As illustrated in FIG. 2, the first transfer section 62 and the second transfer section 63 are disposed to be apart from each other in the arrangement direction X. The combination transport device 64 connects the first transfer section 62 to the second transfer section 63 along the arrangement direction X. In the present example, the first transfer section 62, the second transfer section 63, and the combination transport device 64 are disposed on the front side (a side where respective supports 23 of the first transfer device 22 and the second transfer device 32 are disposed relative to the first guide body 21 and the second guide body 31) relative to the first path 4 and the second path 5. Further, the first transfer section 62 is disposed on the first side X1 in the arrangement direction relative to the second transfer section 63 such that the first transfer section 62 corresponds to the first transfer device 22. As such, in the present embodiment, the first transfer section 62 and the second transfer section 63 are also regarded as the transfer target section 11 to which the transfer device (the first transfer device 22, the second transfer device 32) transfers the article W. Such a configuration allows the first transfer device 22 and the second transfer device 32 to perform a transfer operation at the same time. For example, while the first transfer device 22 performs an operation to transfer the article W to the first transfer section 62, the second transfer device 32 can perform an operation to receive, from the second transfer section 63, the article W transported by the combination transport device 64 from the first transfer section 62. This accordingly makes it possible to increase efficiency of transport of the article W.

In the example of FIG. 5, the combination transport device 64 is constituted by a wagon-type conveyor. More specifically, the combination transport device 64 includes a wagon section 64a, a mounting table 64b on which the article W is placed, and a combination guide body 64c. The wagon section 64a is guided by the combination guide body 64c to move in the arrangement direction X. The mounting table 64b can lift and lower relative to the wagon section 64a and transfers the article W to and from each of the first transfer section 62 and the second transfer section 63 by lifting and lowering. The combination guide body 64c includes rails or the like, for example, and may guide the wagon section 64a along the rails. Note that the combination transport device 64 may be a well-known conveyor such as a roller-type conveyor or a belt-type conveyor other than the wagon-type conveyor or may be a fork-type transfer device. Further, the first transfer section 62 and the second transfer section 63 are shelf bodies for supporting the article W from below. In the example of FIG. 5, the first transfer section 62 and the second transfer section 63 are supported by the combination guide body 64c but may be supported by a side wall of the intermediate cylindrical body 9 as illustrated in FIG. 4. Further, the shelf body may be provided to rotate around a vertical axial center such that the orientation of the article W is changeable freely.

In the present embodiment, as illustrated in FIG. 2, the shared storing section 61 includes at least two article mounting sections 65 on each of which the article W is placeable. The at least two article mounting sections 65 are disposed at the same height. In the example of FIG. 2, the shared storing section 61 includes a plurality of (herein, three) article mounting sections 65. The article W can be transferred to the plurality of article mounting sections 65 by both the first transfer device 22 and the second transfer device 32. For example, the first transfer device 22 transfers the article W to a specific article mounting section 65, and the second transfer device 32 can receive and transport the article W placed on the specific article mounting section 65. In the example illustrated herein, the plurality of article mounting sections 65 is disposed to be sandwiched between the first path 4 and the second path 5. In addition, the plurality of article mounting sections 65 is disposed on a side closer to the transfer device (the first transfer device 22, the second transfer device 32) than the first transfer section 62, the second transfer section 63, and the combination transport device 64. Hereby, the article mounting sections 65 closer to the first transfer device 22 and the second transfer device 32 can be used as shared shelves for the first transfer device 22 and the second transfer device 32. In the meantime, the first transfer section 62 and the second transfer section 63 far from the first transfer device 22 and the second transfer device 32 in comparison with the article mounting sections 65 are not share shelves, and the combination transport device 64 transfers the article W between the first transfer section 62 and the second transfer section 63. As such, the overlap area 6 (herein, the internal space P3 of the intermediate cylindrical body 9) can be effectively utilized. Further, in the above configuration, even in a case where the number of articles W to be transported is large, the articles W can be efficiently transferred between the first transfer device 22 and the second transfer device 32, so that the articles W can be smoothly transported to the conveyor sections 69 or the transport conveyors 95 on respective levels. Note that, in the present example, the plurality of article mounting sections 65 is disposed at the same height as the first transfer section 62 and the second transfer section 63. Here, it is not necessary that “the same height” be strictly the same height, and for example, the plurality of article mounting sections 65 may be disposed at a position vertically deviating from the first transfer device 22 or the second transfer device 32 by around the vertical dimension of the first transfer device 22 or the second transfer device 32. The article mounting section 65 is a shelf body for supporting the article W from below. As such, in the present embodiment, each of the article mounting sections 65 is also regarded as the transfer target section 11 to which the transfer device (the first transfer device 22, the second transfer device 32) transfers the article W.

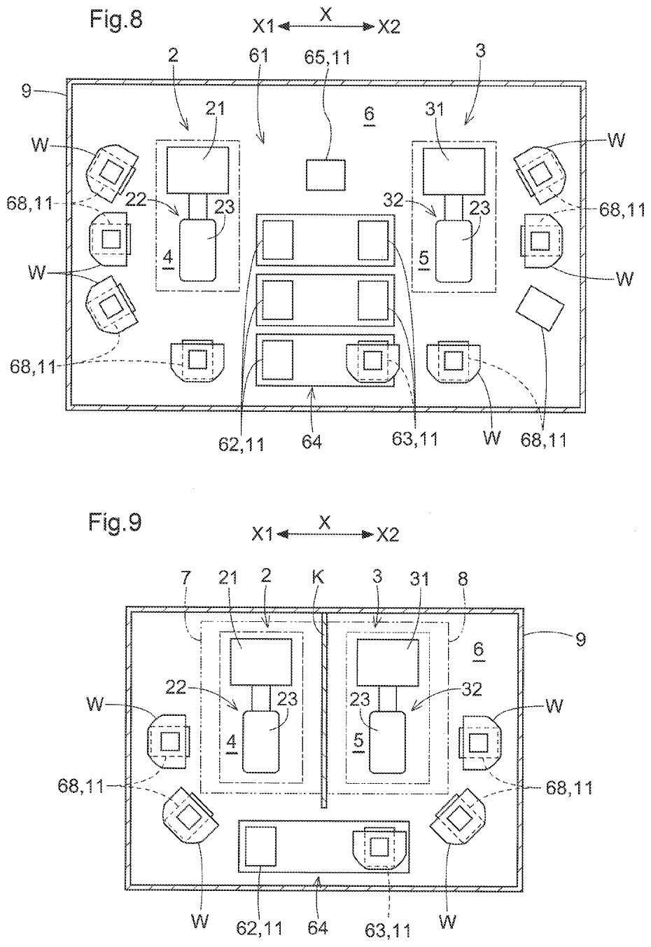

Further, in the present example, the shared storing section 61 includes a plurality of general mounting sections 68. The plurality of general mounting sections 68 is disposed along a horizontal plane to surround the first path 4 and the second path 5. The general mounting sections 68 are disposed on respective outer sides from the first path 4 and the second path 5 in the arrangement direction X or respective outer sides from the first transfer section 62 and the second transfer section 63 in the arrangement direction X. The article W can be transferred to the general mounting section 68 as the transfer target section 11 by the first transfer device 22 or the second transfer device 32. For example, in a plan view, the first transfer device 22 transfers the article W to the general mounting section 68 disposed at a position closer to the first transfer device 22 than the second transfer device 32, from among the general mounting sections 68. Similarly, in a plan view, the second transfer device 32 transfers the article W to the general mounting section 68 disposed at a position closer to the second transfer device 32 than the first transfer device 22, from among the general mounting sections 68. Note that the general mounting section 68 is a shelf body for supporting the article W from below. As such, since a plurality of articles W can be stored in the shared storing section 61, it is possible to temporarily store the article W or switch transport orders of the articles W, for example. Further, in the present example, the shared storing section 61 includes the first transfer section 62, the second transfer section 63, the plurality of article mounting sections 65, and the plurality of general mounting sections 68 as the transfer target sections 11, so that the overlap area 6 (herein, the internal space P3 of the intermediate cylindrical body 9) can be effectively utilized. Note that, in FIG. 1, the plurality of shared storing sections 61 provided in the intermediate cylindrical body 9 has the same configuration. However, the plurality of shared storing sections 61 may have configurations different from each other. For example, in the plurality of shared storing sections 61, the example of FIG. 2 described above, the example of FIG. 8 described later, and the like may be combined as needed, or the configurations illustrated in those examples may be modified.

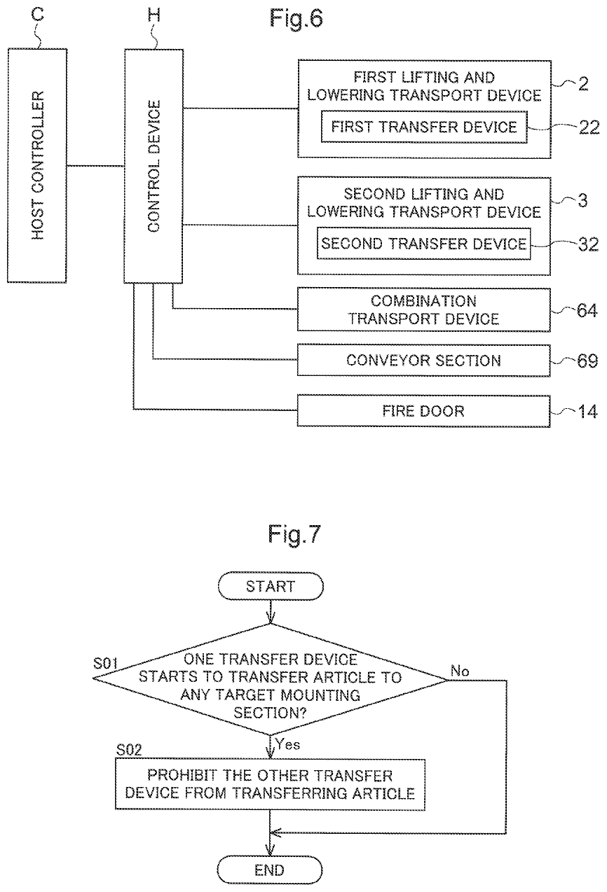

As illustrated in FIG. 6, the article transport facility 100 includes a control device H configured to control the first lifting and lowering transport device 2, the second lifting and lowering transport device 3, the combination transport device 64, the fire door 14, and the conveyor section 69. The control device H includes a processor such as a microcomputer and a peripheral circuit such as a memory, and each function of the control device H is implemented in collaboration of these pieces of hardware and a program executed on hardware such as the processor. The control device H is mutually communicably connected to a host controller C configured to control the whole clean room or the like where the article transport facility 100 is provided. The control device H acquires a command from the host controller C and controls the first lifting and lowering transport device 2, the second lifting and lowering transport device 3, the combination transport device 64, the fire door 14, and the conveyor section 69 in response to the content of the command thus acquired.

In the examples of FIGS. 1 and 2, the control device H can transport the article W received from the transport conveyor 95 or the conveyor section 69 on a specific level to the transport conveyor 95 or the conveyor section 69 on a different level. For example, the control device H can control the first transfer device 22 such that the first transfer device 22 transports the article W received from the conveyor section 69 on a specific level (the fourth level or the fifth level) to one of the plurality of shared storing sections 61 in the overlap area 6. As illustrated in FIG. 2, the control device H can control the first transfer device 22 and the second transfer device 32 such that the transported article W is transferred to the second transfer device 32 via the article mounting section 65 in the shared storing section 61. Further, the control device H can control the first transfer device 22, the second transfer device 32, and the combination transport device 64 such that the article W transferred from the first transfer device 22 to the first transfer section 62 is transported to the second transfer section 63, and after that, the second transfer device 32 receives the article W on the second transfer section 63. Further, the control device H can control the first transfer device 22 such that the article W is transferred to the general mounting section 68 and also control each device such that, after another article W is transported to another level via the shared storing section 61, the article W placed on the general mounting section 68 is transferred to the second transfer device 32 via the article mounting section 65 and the combination transport device 64. The control device H can control the second transfer device 32 such that the article W received from the first transfer device 22 is transported to the transport conveyor 95 (the first level) or the conveyor section 69 (the first level or the second level) on a given level (herein, the first level or the second level). Note that this also applies to a case where the article W is transferred from the second transfer device 32 to the first transfer device 22 and transported.

Further, the control device H can control the first transfer device 22 and the second transfer device 32 such that the article W is transported to the transport conveyor 95 connected to the intermediate cylindrical body 9 or the conveyor section 69 provided on a level (herein, the third level) where the intermediate cylindrical body 9 is provided.

In the present embodiment, as illustrated in FIGS. 4, 7, in a case where the first transfer device 22 and the second transfer device 32 are disposed at the same height and one transfer device out of the first transfer device 22 and the second transfer device 32 starts to transfer the article W to a target mounting section 66 that is either of at least two article mounting sections 65 disposed at the same height, the other transfer device is prohibited from transferring the article W to the target mounting section 66. In the example of FIG. 2, in a case where one of three article mounting sections 65 is the target mounting section 66 for the first transfer device 22, the control device H prohibits the second transfer device 32 from transferring the article W to the target mounting section 66. Similarly, in a case where one of the three article mounting sections 65 is the target mounting section 66 for the second transfer device 32, the control device H prohibits the first transfer device 22 from transferring the article W to the target mounting section 66. The following further gives description with reference to a control flow diagram.

In a case where the control device H determines that one transfer device out of the first transfer device 22 and the second transfer device 32 starts to transfer the article W to the target mounting section 66 (S01: Yes), the control device H prohibits the other transfer device (the first transfer device 22 or the second transfer device 32) from transferring the article W to the target mounting section 66 (S02). In this case, the control device H controls the other transfer device such that the other transfer device transfers the article W to the article mounting section 65 that is not the target mounting section 66. In the example of FIG. 2, the control device H can control the transfer device prohibited from transferring the article W to the target mounting section 66 such that the transfer device transfers the article W to the general mounting section 68.

In the present embodiment, as illustrated in FIG. 6, the control device H controls the fire doors 14 provided in the coupler 72 between the first cylindrical body 7 and the intermediate cylindrical body 9 and the coupler 82 between the second cylindrical body 8 and the intermediate cylindrical body 9. In a case where the host controller C receives an alarm signal indicative of fire, for example, the control device H controls the fire doors 14 such that the fire doors 14 are switched from an open state to a closed state, in response to command information received from the host controller C.

### Other Embodiments

Next will be described other embodiments of the article transport facility.

(1) The above embodiment has described, as an example, the configuration in which the first path 4 and the second path 5 are disposed in the same range in the whole vertical area of one level (the third level in the example of FIG. 1), but the present invention is not limited to this. For example, the first path 4 and the second path 5 may be disposed in the same range over a plurality of levels. Further, the first path 4 and the second path 5 may be disposed in the same range in a partial vertical area of one level.

(2) The above embodiment has described, as an example, the configuration in which the first cylindrical body 7 contains the first lifting and lowering transport device 2, and the second cylindrical body 8 contains the second lifting and lowering transport device 3, but the present invention is not limited to this. For example, the first cylindrical body 7 may be provided to contain only the first transfer device 22 to include the first path 4 in the internal space P1, and the second cylindrical body 8 may be provided to contain only the second transfer device 32 to include the second path 5 in the internal space P2.

(3) The above embodiment has described, as an example, the configuration in which the first arrangement space S1 where other members or devices are arrangeable is provided on a side vertically opposite to the first cylindrical body 7 across the intermediate cylindrical body 9, and the second arrangement space S2 where other members or devices are arrangeable is provided on a side vertically opposite to the second cylindrical body 8 across the intermediate cylindrical body 9, but the present invention is not limited to this. For example, only either of the first arrangement space S1 and the second arrangement space S2 may be provided.

(4) The above embodiment has described, as an example, the configuration in which at least one of the coupler 72 between the first cylindrical body 7 and the intermediate cylindrical body 9 and the coupler 82 between the second cylindrical body 8 and the intermediate cylindrical body 9 includes the fire door 14, but the present invention is not limited to this. For example, the coupler 72 between the first cylindrical body 7 and the intermediate cylindrical body 9 and the coupler 82 between the second cylindrical body 8 and the intermediate cylindrical body 9 include no fire door 14. In this case, for example, one or more fire doors 14 can be provided in the intermediate cylindrical body 9 to partition off the internal space P3 of the intermediate cylindrical body 9. Alternatively, the fire door 14 can be also provided in a portion of the first cylindrical body 7 which portion is other than the coupler 72 with the intermediate cylindrical body 9 or in a portion of the second cylindrical body 8 which portion is other than the coupler 82 with the intermediate cylindrical body 9.

(5) The above embodiment has described, as an example, the configuration in which the shared storing section 61 includes one first transfer section 62 to which the first transfer device 22 transfers the article W, one second transfer section 63 to which the second transfer device 32 transfers the article W, and one combination transport device 64 configured to transport the article W between the first transfer section 62 and the second transfer section 63, but the present invention is not limited to this. For example, the shared storing section 61 does not necessarily need to include the first transfer section 62, the second transfer section 63, and the combination transport device 64. In the meantime, the shared storing section 61 can include a plurality of first transfer sections 62, a plurality of second transfer sections 63, and a plurality of combination transport devices 64. Such an example is illustrated in FIG. 8. In the example of FIG. 8, three first transfer sections 62 and three second transfer sections 63 are provided, and three combination transport devices 64 are also provided to correspond to them.

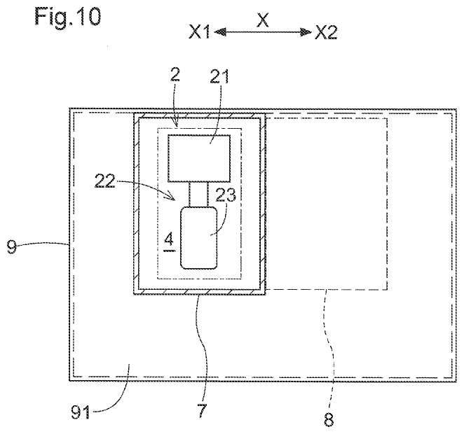

(6) The above embodiment has described, as an example, the configuration in which the shared storing section 61 includes at least two article mounting sections 65 on each of which the article W is placeable, but the present invention is not limited to this. For example, the shared storing section 61 may include one article mounting section 65. Such an example is illustrated in FIG. 8. In the example of FIG. 8, a plurality of combination transport devices 64 and a single article mounting section 65 are arranged between the first path 4 and the second path 5. In addition, the article mounting section 65 is disposed at a position relatively apart from respective supports 23 of the first transfer device 22 and the second transfer device 32. As such, the article W is transferred between the first transfer device 22 and the second transfer device 32 by use of the combination transport device 64 at a position relatively close to each support 23, and the article mounting section 65 is provided at a position where the article W is hard to be transported by the combination transport device 64, the position being apart from each support 23. Hereby, the overlap area 6 (herein, the internal space P3 of the intermediate cylindrical body 9) can be effectively utilized. Further, the shared storing section 61 does not necessarily need to include the article mounting section 65. Such an example is illustrated in FIG. 9. In FIG. 9, no article mounting section 65 is disposed between the first transfer device 22 and the second transfer device 32, and a set of the first transfer section 62, the second transfer section 63, and the combination transport device 64 is provided on the front side relative to the first path 4 and the second path 5. When the article mounting section 65 or the like is not disposed between the first transfer device 22 and the second transfer device 32, the first path 4 and the second path 5 can be disposed close to each other in the arrangement direction X, as illustrated in FIG. 10. In this case, the first cylindrical body 7 and the second cylindrical body 8 can be disposed adjacent to each other in the arrangement direction X, and in addition, the intermediate cylindrical body 9 can be made small. This makes it possible to downsize the article transport facility 100. Moreover, in FIG. 9, in the overlap area 6, a wall K is provided between the first path 4 and the second path 5. The wall K may be provided as one member of the intermediate cylindrical body 9 or may be a common side wall portion for the first cylindrical body 7 and the second cylindrical body 8 adjacent to each other. Alternatively, at least one of the first cylindrical body 7 and the second cylindrical body 8 may be disposed to penetrate into the internal space P3 of the intermediate cylindrical body 9 (an alternate long and two short dashes line in FIG. 2).

(7) The above embodiment has described, as an example, the configuration in which, in a case where the first transfer device 22 and the second transfer device 32 are disposed at the same height and one transfer device out of the first transfer device 22 and the second transfer device 32 starts to transfer the article W to the target mounting section 66 that is either of at least two article mounting sections 65 disposed at the same height, the other transfer device is prohibited from transferring the article W to the target mounting section 66, but the present invention is not limited to this. For example, both the first transfer device 22 and the second transfer device 32 may perform a transfer operation to the target mounting section 66 at the same time. For example, when the second transfer device 32 starts an operation of receiving the article W from the target mounting section 66 after the first transfer device 22 starts an operation of transferring (placing) the article W to the target mounting section 66 but before the article W is placed on the target mounting section 66, it is possible to shorten a period for transferring the article W between the first transfer device 22 and the second transfer device 32.

(8) Note that the configurations disclosed in the above embodiment can be applied in combination with the configurations disclosed in other embodiments (including combinations of the embodiments described as the other embodiments) as long as no inconsistency occurs. In terms of other configurations, the embodiment disclosed in the present specification is also just an example in all respects. Accordingly, various modifications can be made appropriately as far as it does not deviate from the scope of this disclosure.

### Overview of Embodiment

The following describes the overview of the article transport facility described above.

The article transport facility according to this disclosure is an article transport facility for transporting an article over a plurality of levels and includes: a first lifting and lowering transport device including a first guide body disposed to extend vertically, and a first transfer device configured to lift and lower on a first path along the first guide body and to transfer the article to and from a transfer target section; and a second lifting and lowering transport device including a second guide body disposed to extend vertically, and a second transfer device configured to lift and lower on a second path along the second guide body and to transfer the article to and from the transfer target section. The first path and the second path are disposed not to overlap with each other as viewed vertically. The first path has a first target area including a lower end portion of the first path, the second path has a second target area including an upper end portion of the second path, and the first target area and the second target area are disposed in the same vertical range. The first transfer device and the second transfer device are both able to transfer the article to a shared storing section in which the article is storable, the shared storing section being provided in an overlap area disposed in the same vertical range as the first target area and the second target area.

With this configuration, both the first transfer device and the second transfer device can store the article in the shared storing section and transfer the article to each other via the shared storing section. Accordingly, it is possible to easily secure a storage place for articles and to transfer articles over the whole area in a liftable range of the first transfer device and in a liftable range of the second transfer device. Further, in the above configuration, since the path of the first transfer device and the path of the second transfer device are disposed not to overlap with each other as viewed vertically, it is possible to dispose the first transfer device and the second transfer device at the same height. As a result, in a case where the first transfer device and the second transfer device separately lift and lower, they do not restrict each other, and hereby, it is possible to easily enhance article transport efficiency as the whole facility.

This configuration allows the article transport facility for transporting an article over a plurality of levels to secure a storage place for articles and to enhance article transport efficiency.

Here, it is preferable that: the article transport facility further include a first cylindrical body disposed to extend vertically and containing the first lifting and lowering transport device, a second cylindrical body disposed to extend vertically and containing the second lifting and lowering transport device, and an intermediate cylindrical body containing the first guide body and the second guide body in the overlap area and provided with the shared storing section; the first cylindrical body be disposed above the intermediate cylindrical body and have a lower end portion connected to the intermediate cylindrical body; the second cylindrical body be disposed below the intermediate cylindrical body and have an upper end portion connected to the intermediate cylindrical body; and the first cylindrical body and the second cylindrical body be disposed not to overlap with each other as viewed vertically.

In this configuration, when the first cylindrical body has a size that can contain the first lifting and lowering transport device above the intermediate cylindrical body, it is not necessary that the first cylindrical body be made larger than this. In view of this, by restraining the size of the first cylindrical body as viewed vertically, it is possible to effectively use the space around the first cylindrical body. The same can be said for the second cylindrical body, and thus, it is possible to effectively use the space around the second cylindrical body. The intermediate cylindrical body has a size that can contain the first guide body, the second guide body, and the shared storing section.

When the first cylindrical body, the second cylindrical body, and the intermediate cylindrical body are provided separately, and the first cylindrical body and the second cylindrical body are disposed not to overlap with each other as viewed vertically, each cylindrical body can have an appropriate size, and space efficiency can be easily raised as the whole facility.

It is also preferable that: the first cylindrical body be provided on a side vertically opposite across the intermediate cylindrical body to a first arrangement space where other members or devices are arrangeable; and the second cylindrical body be provided on a side vertically opposite across the intermediate cylindrical body to a second arrangement space where other members or devices are arrangeable.

With this configuration, it is possible to dispose other members or devices in the first arrangement space or the second arrangement space, so that space efficiency can be easily raised effectively as the whole facility.

Further, it is preferable that: the article transport facility include a fire door provided in at least one of a coupler between the first cylindrical body and the intermediate cylindrical body and a coupler between the second cylindrical body and the intermediate cylindrical body; the fire door provided in the coupler between the first cylindrical body and the intermediate cylindrical body be configured to expose and block an area which overlaps with an internal space of the first cylindrical body as viewed vertically and which does not overlap with an internal space of the second cylindrical body as viewed vertically; and the fire door provided in the coupler between the second cylindrical body and the intermediate cylindrical body be configured to expose and block an area which overlaps with the internal space of the second cylindrical body as viewed vertically and which does not overlap with the internal space of the first cylindrical body as viewed vertically.

With this configuration, it is possible to reduce an area to be exposed and blocked by the fire door as viewed vertically in comparison with a case where a fire door for exposing and blocking an internal space of the intermediate cylindrical body is provided. This accordingly makes it possible to easily reduce the weight and the cost of the fire door.

Further, it is preferable that the shared storing section include a first transfer section to which the first transfer device transfers the article, a second transfer section to which the second transfer device transfers the article, and a combination transport device configured to transport the article between the first transfer section and the second transfer section.

With this configuration, the first transfer device and the second transfer device can transfer articles to the shared storing section at the same time.

Further, with this configuration, the article transferred from the first transfer device to the first transfer section can be moved to the second transfer section by the combination transport device and transferred to the second transfer device. Similarly, the article transferred from the second transfer device to the second transfer section can be moved to the first transfer section by the combination transport device and transferred to the first transfer device. This accordingly makes it possible to avoid the first transfer device and the second transfer device from coming into contact with each other and to efficiently transfer the article. Thus, it is possible to easily enhance article transport efficiency as the whole facility.

Further, it is preferable that: the shared storing section include at least two article mounting sections on each of which the article is placeable; and the at least two article mounting sections be disposed at the same height.

With this configuration, even when the first transfer device and the second transfer device are disposed at the same height, the first transfer device and the second transfer device can simultaneously transfer respective articles to and from separate article mounting sections disposed at the same height. This accordingly makes it possible to easily enhance article transport efficiency as the whole facility.

Besides, with this configuration, the installation area of the facility as viewed vertically can be easily restrained in comparison with a case where the combination transport device is provided.

Further, it is preferable that, in a case where the first transfer device and the second transfer device are disposed at the same height and either of the at least two article mounting sections disposed at the same height is a target mounting section to which one of the first transfer device and the second transfer device starts to transfer the article, the other one of the first transfer device and the second transfer device be prohibited from transferring the article to the target mounting section.

With this configuration, when the first transfer device and the second transfer device are disposed at the same height, it is possible to avoid such a situation that the first transfer device and the second transfer device transfer respective articles to one article mounting section at the same time.

The article transport facility according to this disclosure should be able to achieve at least one of the above effects.

What is claimed is:

1. An article transport facility for transporting an article over a plurality of levels, comprising:
a first lifting and lowering transport device comprising a first guide body disposed to extend vertically, and a first transfer device configured to lift and lower on a first path along the first guide body and to transfer the article to and from a transfer target section; and
a second lifting and lowering transport device comprising a second guide body disposed to extend vertically, and a second transfer device configured to lift and lower on a second path along the second guide body and to transfer the article to and from the transfer target section, and
wherein:
the first path and the second path are disposed not to overlap with each other as viewed vertically,
the first path has a first target area comprising a lower end portion of the first path, the second path has a second target area comprising an upper end portion of the second path, and the first target area and the second target area are disposed in the same vertical range,
the first transfer device and the second transfer device are both able to transfer the article to a shared storing section in which the article is storable, and the shared storing section is provided in an overlap area disposed in the same vertical range as the first target area and the second target area.

2. The article transport facility according to claim 1, further comprising:
a first cylindrical body disposed to extend vertically and containing the first lifting and lowering transport device;
a second cylindrical body disposed to extend vertically and containing the second lifting and lowering transport device; and
an intermediate cylindrical body containing the first guide body and the second guide body in the overlap area and provided with the shared storing section, and
wherein:
the first cylindrical body is disposed above the intermediate cylindrical body and has a lower end portion connected to the intermediate cylindrical body,
the second cylindrical body is disposed below the intermediate cylindrical body and has an upper end portion connected to the intermediate cylindrical body, and
the first cylindrical body and the second cylindrical body are disposed not to overlap with each other as viewed vertically.

3. The article transport facility according to claim 2, wherein:
the first cylindrical body is provided on a side vertically opposite across the intermediate cylindrical body to a first arrangement space where other members or devices are arrangeable, and
the second cylindrical body is provided on a side vertically opposite across the intermediate cylindrical body to a second arrangement space where other members or devices are arrangeable.

4. The article transport facility according to claim 2, further comprising:
a fire door provided in at least one of a coupler between the first cylindrical body and the intermediate cylindrical body and a coupler between the second cylindrical body and the intermediate cylindrical body, and
wherein:
the fire door provided in the coupler between the first cylindrical body and the intermediate cylindrical body is configured to expose and block an area which overlaps with an internal space of the first cylindrical body as viewed vertically and which does not overlap with an internal space of the second cylindrical body as viewed vertically, and
the fire door provided in the coupler between the second cylindrical body and the intermediate cylindrical body is configured to expose and block an area which overlaps with the internal space of the second cylindrical body as viewed vertically and which does not overlap with the internal space of the first cylindrical body as viewed vertically.

5. The article transport facility according to claim 1, wherein:
the shared storing section comprises a first transfer section to which the first transfer device transfers the article, a second transfer section to which the second transfer device transfers the article, and a combination transport device configured to transport the article between the first transfer section and the second transfer section.

6. The article transport facility according to claim 1, wherein:
the shared storing section comprises at least two article mounting sections on each of which the article is placeable, and
the at least two article mounting sections are disposed at the same height.

7. The article transport facility according to claim 6, wherein:
in a case where the first transfer device and the second transfer device are disposed at the same height and either of the at least two article mounting sections disposed at the same height is a target mounting section to which one of the first transfer device and the second transfer device starts to transfer the article, the other one of the first transfer device and the second transfer device is prohibited from transferring the article to the target mounting section.
